(19) United States
(12) Patent Application Publication
(10) Pub. No.: US 2009/0173999 A1
(43) Pub. Date: Jul. 9, 2009

(54) FIELD EFFECT TRANSISTOR WITH GATE HAVING VARYING SHEET RESISTANCE

(76) Inventors: Remis Gaska, Columbia, SC (US); Alexei Koudymov, Troy, NY (US); Michael Shur, Latham, NY (US); Grigory Simin, Columbia, SC (US)

Correspondence Address: HOFFMAN WARNICK LLC, 75 STATE STREET, 14TH FLOOR, ALBANY, NY, 12207, US

(21) Appl. No.: 12/350,625

(22) Filed: Jan. 8, 2009

Related U.S. Application Data
(60) Provisional application No. 61/010,425, filed on Jan. 8, 2008.

(51) Int. Cl. H01L 29/78

(52) U.S. Cl. 257/364; 257/E29.255

(57) ABSTRACT

A field effect transistor (FET) comprising a gate structure that includes at least one gate having a varying sheet resistance in a direction between a source contact and a drain contact. In an illustrative embodiment, the FET can be configured to operate as a radio frequency switch. In this case, the FET can provide improved performance with respect to both the off-state capacitances and radio frequency isolations over similar FETs implemented with typical gates.

### REFERENCE TO PRIOR APPLICATION

The current application claims the benefit of co-pending U.S. Provisional Application No. 61/010,425, titled “Large periphery integrated radio-frequency field-effect transistor switch,” which was filed on 8 Jan. 2008, and which is hereby incorporated by reference.

### TECHNICAL FIELD

The disclosure relates generally to field effect transistors, and more particularly, to a field effect transistor with an improved gate design for use as a radio frequency switch.

### BACKGROUND ART

Solid state radio frequency (RF) switches are important components of Radar transmit/receive (T/R) modules, satellite communication systems, Joint Tactical Radio Systems (JTRS), and the like. A promising RF switch technology uses Heterostructure Field Effect Transistors (HFETs). Recently, high power switches made of AlGaN/GaN HFETs demonstrated superior performance over other RF switching devices in terms of maximum power density, bandwidth, operating temperature, and breakdown voltage.

Many applications, including JTRS and low-noise receivers, require RF switches with a very low insertion loss, e.g., typically below 0.1 dB. A low loss switch dissipates little RF power. As a result, it can be fabricated over a low cost substrate, such as sapphire. Low insertion loss in an HFET is due to a high channel conductance of the device, which is proportional to a total length of the device periphery. Exceptionally high 2D electron gas densities at the AlGaN/GaN interface make a group III-Nitride HFET with a total periphery of two to five mm an ideal candidate for RF switching applications.

The feasibility of high-power broad-band monolithically integrated group III-Nitride HFET RF switches has been demonstrated. Large signal analysis and experimental data for a large periphery group III-Nitride switch indicate that the switch can achieve switching powers exceeding +40 . . . +50 dBm. However, at frequencies corresponding to the RF frequency band, the OFF state isolation achieved by such a switch is limited by its internal parasitic capacitance, which is also proportional to the total length of the device periphery.

### SUMMARY OF THE INVENTION

Aspects of the invention provide a field effect transistor (FET) comprising a gate structure that includes at least one gate having a varying sheet resistance in a direction between a source contact and a drain contact. In an illustrative embodiment, the FET can be configured to operate as a radio frequency switch. In this case, the FET can provide improved performance with respect to both the off-state capacitances and radio frequency isolations over similar FETs implemented with typical gates.

A first aspect of the invention provides a field effect transistor (FET) comprising: a device channel; a source contact to the device channel; a drain contact to the device channel; and a gate structure located over the device channel and between the source contact and the drain contact, wherein the gate structure includes at least one gate having a varying sheet resistance in a direction between the source contact and the drain contact.

A second aspect of the invention provides a circuit comprising: a radio frequency (RF) signal input; a RF signal output; a field effect transistor (FET) configured to operate as a radio frequency switch, the FET including: a device channel; a source contact to the device channel electrically connected to the RF signal input; a drain contact to the device channel electrically connected to at least one of: the RF signal output or a ground; and a gate structure located over the device channel and between the source contact and the drain contact, wherein the gate structure includes at least one gate having a varying sheet resistance in a direction between the source contact and the drain contact.

A third aspect of the invention provides a field effect transistor (FET) comprising: a gate structure located over a device channel and between a source contact to the device channel and a drain contact to the device channel, wherein the gate structure includes at least one gate having a varying sheet resistance in a direction between the source contact and the drain contact.

Other aspects of the invention provide methods, systems, program products, and methods of using and generating each, which include and/or implement some or all of the actions described herein. The illustrative aspects of the invention are designed to solve one or more of the problems herein described and/or one or more other problems not discussed.

### BRIEF DESCRIPTION OF THE DRAWINGS

These and other features of the disclosure will be more readily understood from the following detailed description of the various aspects of the invention taken in conjunction with the accompanying drawings that depict various aspects of the invention.

FIG. 1A shows a cross section of an illustrative FET according to an embodiment.

FIG. 1B shows a schematic representation of the FET of FIG. 1A operating as an RF switch in the off state according to an embodiment.

FIG. 2 shows a cross section of another illustrative FET according to an embodiment.

FIG. 3 shows a cross section of still another illustrative FET according to an embodiment.

FIG. 4 shows simulated off-state capacitances and radio frequency isolations as a function of the number of gates for illustrative field effect transistors according to an embodiment.

FIG. 5 shows an illustrative RF coplanar waveguide circuit according to an embodiment.

FIG. 6 shows an illustrative field effect transistor layout according to an embodiment.

It is noted that the drawings may not be to scale. The drawings are intended to depict only typical aspects of the invention, and therefore should not be considered as limiting the scope of the invention. In the drawings, like numbering represents like elements between the drawings.

### DETAILED DESCRIPTION OF THE INVENTION

As indicated above, aspects of the invention provide a field effect transistor (FET) comprising a gate structure that includes at least one gate having a varying sheet resistance in a direction between a source contact and a drain contact. In an illustrative embodiment, the FET can be configured to operate as a radio frequency switch. In this case, the FET can provide improved performance with respect to both the off-state capacitances and radio frequency isolations over similar FETs implemented with typical gates. As used herein, unless otherwise noted, the term “set” means one or more (i.e., at least one) and the phrase “any solution” means any now known or later developed solution.

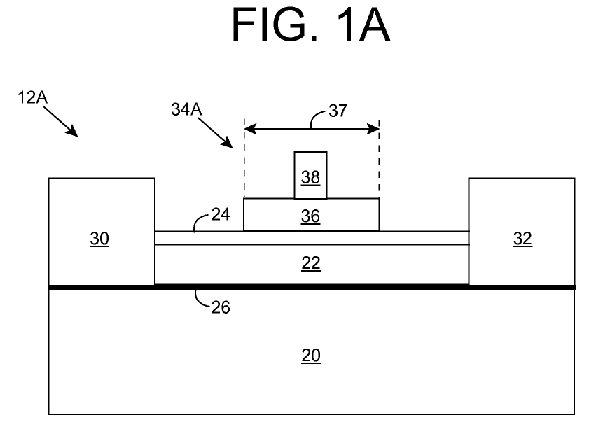

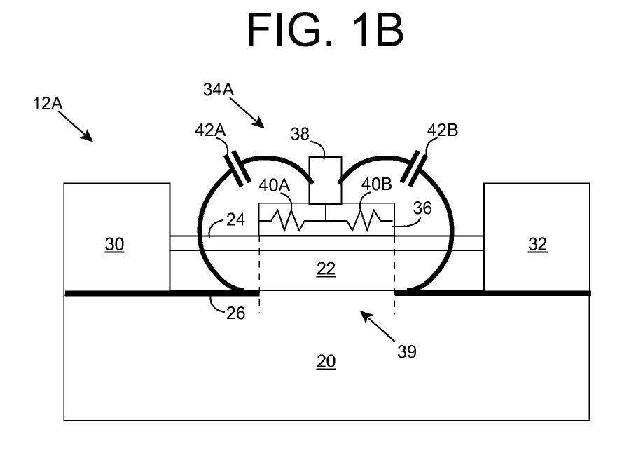

Turning to the drawings, FIG. 1A shows a cross section of an illustrative FET 12A according to an embodiment. FET 12A comprises a heterostructure FET including a first structure 20, a second structure 22, and an insulating structure 24. A device channel 26 (e.g., a two-dimensional device channel) is formed at an interface of first structure 20 and second structure 22. First and second structures 20, 22 can each include any number of one or more layers of materials selected from any now known or later developed material system, which will form device channel 26. For example, structures 20, 22 can comprise one or more layers of materials selected from the group-III nitride material system (e.g., Al_{X}In_{Y}Ga_{1-X-Y}N, where 0≦X, Y≦1, and X+Y≦1 and/or alloys thereof) deposited on any type of substrate (e.g., sapphire). In an embodiment, first structure 20 comprises a buffer layer and second structure 22 comprises a barrier layer. Further, insulating structure 24 can comprise one or more layers of any type of insulating material, such as a dielectric. To this extent, insulating structure 24 can include one or more of any type of uniform or composite dielectric layers. For example, insulating structure 24 can include oxygen containing dielectric materials (e.g., SiO₂, HfO₂, or the like), a SiN compound (e.g., SiN, Si₃N₄), and/or the like.

Further, FET 12A includes a source contact 30 and a drain contact 32, each of which forms a contact to channel 26. Source contact 30 and drain contact 32 can comprise any type of contact material and can be formed using any solution. In an embodiment, contacts 30, 32 comprise Ohmic contacts comprising materials selected from the group-III nitride material system. A gate structure 34A is shown located on insulating structure 24 to form an insulated gate structure. However, it is understood that in another embodiment, gate structure 34A can be located directly on second structure 22. Further, while illustrative HFETs are shown and described herein, it is understood that a gate structure having a varying sheet resistance as shown and described herein can be implemented on any variation of FET now known or later developed, such as a junction FET, an insulated gate FET, a metal semiconductor FET, a metal oxide semiconductor FET, a metal insulator semiconductor FET, high electron mobility transistor, double heterostructure FET, etc.

Gate structure 34A comprises at least one gate (e.g., a metal stripe) having a sheet resistance that varies along a corresponding width 37 of the gate between source contact 30 and drain contact 32. As illustrated in this embodiment, gate structure 34A comprises a composite gate including a first layer 36 located directly on insulating structure 24 and a second layer 38 located directly on first layer 36. First layer 36 has a larger width within the space between source contact 30 and drain contact 32 than second layer 38. Additionally, each layer 36, 38 can comprise a different sheet resistance, e.g., first layer 36 can have a sheet resistance that is higher than the sheet resistance of the second layer 38. As a result, first layer 36 can have a higher sheet resistance and cover a wider area of the space between source contact 30 and drain contact 32 than second layer 38. This configuration creates multiple adjacent regions of the gate having different sheet resistances. In particular, the outer regions of the gate, which include only first layer 36, will comprise a first sheet resistance, whereas the inner region of the gate, which includes both first layer 36 and second layer 38, will comprise a second sheet resistance different from the first sheet resistance. The variation in sheet resistance exceeds unintentional, natural variations that may occur during a manufacturing process. In an embodiment, the two sheet resistances differ by at least a factor of three. In a more specific embodiment, the two sheet resistances differ by at least a factor of ten. However, it is understood that any variation of sheet resistance can be utilized.

In an illustrative embodiment of FET 12A, first structure 20 comprises a sapphire substrate, a GaN buffer layer located thereon, and a second GaN layer located on the buffer layer, while second structure 22 comprises an AlGaN layer. Further, FET 12A comprises approximately 200 micrometer by 50 micrometer rectangular source contact 30 and drain contact 32, separated by approximately five micrometers. Within the space between source contact 30 and drain contact 32, a first layer 36 comprising amorphous silicon and having a width of approximately 0.5 to 1 micrometers and a thickness of approximately 0.15 micrometers is located. A second layer 38 comprising metal (e.g., gold) and having a width of approximately 0.15 to 0.3 micrometers is located on first layer 36.

In an illustrative application, FET 12A is implemented as a switch within a radio frequency (RF) circuit. For example, gate structure 34A can be utilized to selectively allow an RF signal to pass along channel 26 between source 30 and drain 32. In this case, gate structure 34A can have a different sheet resistance along the RF signal path 26 (e.g., in a direction between source 30 and drain 32). Gate structure 34A can provide a lower equivalent off-state capacitance at microwave frequencies than various alternative gate designs, which can result in a significant improvement in off-state isolation at high operating frequencies and/or enable FET 12A to operate over a broader frequency range than similar FETs including various alternative gate designs. As a result, FET 12A can provide low loss and/or high isolation RF switching for RF circuits in high power and/or high frequency applications.

FIG. 1B shows a schematic representation of FET 12A operating as an RF switch in the off state, e.g., a negative direct current voltage bias is applied to second layer 38, according to an embodiment. The negative voltage bias at second layer 38 forms a depletion region 39 by depleting channel 26 under first layer 36. Current research indicates that the low off-capacitance achieved when FET 12A is operated as an RF switch is due to an extended length of a depletion region 39 under first layer 36. In particular, research indicates that a control bias applied at second layer 38 develops a reverse potential that depletes the channel 26 throughout an entire length of first layer 36. Resistors 40A-B and capacitors 42A-B represent an equivalent RC circuit of gate structure 34A with respect to channel 36. In an embodiment, an equivalent RC time constant, τ_{RC}, associated with second layer 38 and channel 26 meets the following condition: τ_{RC}<τ_{SW}, τ_{RC}>(2πf_{MIN})⁻¹, where τ_{SW} is the characteristic switching time and f_{MIN} is the minimal operating frequency of the RF switch.

Returning to FIG. 1A, as discussed herein, gate structure 34A includes a gate having a sheet resistance that varies along its width 37 within the space between source contact 30 and drain contact 32. In this embodiment, gate structure 34A comprises a composite gate having a first sheet resistance in a portion of the composite gate that includes both layers 36, 38, and a second sheet resistance in portions of the composite gate that include only layer 36 (e.g., the outer portions of the composite gate). However, it is understood that various alternative implementations are possible. For example, gate structure 34A could comprise a gate formed using a single layer of material having a varying sheet resistance along its width 37. Further, it is understood that a gate can comprise any number of regions of differing sheet resistance and/or can have a sheet resistance that continuously varies along its width 37.

In an embodiment, when multiple layers, such as layers 36, 38, are included in a composite gate of gate structure 34A, a layer having a higher sheet resistance is wider than each layer in the composite gate having a lower sheet resistance. For example, a width of a layer having the higher sheet resistance can be two to ten times a width of a layer in the same composite gate having a lower sheet resistance. However, it is understood that this range is only illustrative. Additionally, it is understood that the relative order of the layers within a composite gate can vary.

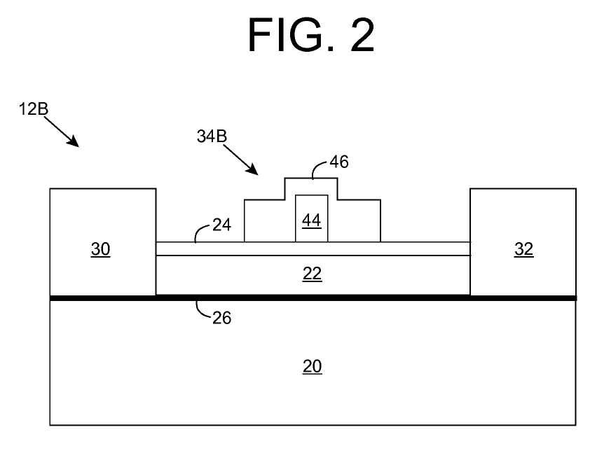

To this extent, FIG. 2 shows a cross section of another illustrative FET 12B according to an embodiment. As illustrated, FET 12B includes a gate structure 34B having a single composite gate that includes a first layer 44 located directly on insulating structure 24, and a second layer 46 located directly on both insulating structure 24 and first layer 44. In this case, second layer 46 has a larger width within the space between source contact 30 and drain contact 32 than first layer 44. Additionally, each layer 44, 46 can comprise a different sheet resistance, e.g., first layer 44 can have a sheet resistance that is lower than a sheet resistance of the second layer 46.

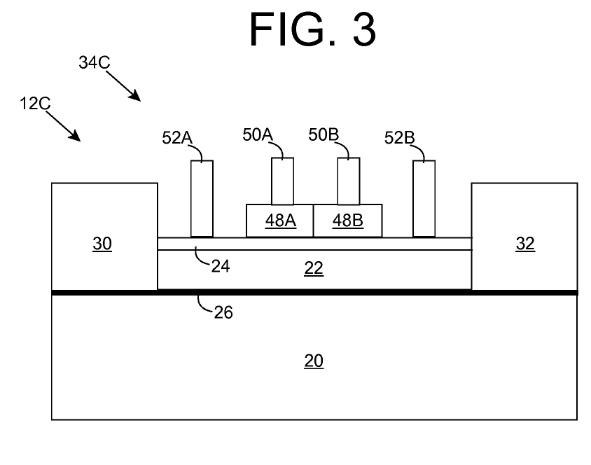

When a gate structure according to an embodiment of the invention includes multiple gates, one or more gates can have varying sheet resistance, while zero or more gates can have a uniform sheet resistance. For example, FIG. 3 shows a cross section of another illustrative FET 12C according to an embodiment. As illustrated, FET 12C includes a gate structure 34C that includes a first compound gate including layers 48A, 50A and a second compound gate including layers 48B, 50B. As discussed with respect to FIG. 1A, layers 48A, 48B can have a higher sheet resistance than layers 50A, 50B, respectively. Additionally, gate structure 34C includes two additional gates including single layers 52A, 52B, respectively, each of which can comprise a uniform sheet resistance. In this configuration, gate structure 34C can comprise two gates having varying sheet resistances along the corresponding widths within the space between source contact 30 and drain contact 32, and two gates having uniform sheet resistances along the corresponding widths within the space between source contact 30 and drain contact 32.

While layers 48A, 48B are shown abutting, it is understood that layers 48A, 48B can be spaced apart. Further, layers 48A, 48B could comprise a single layer having multiple narrower layers 50A, 50B located thereon. Still further, while gate structure 34C is shown including four gates with two interior gates having varying sheet resistances and two exterior single layer gates having uniform sheet resistances, it is understood that a multi-gate gate structure 34C can include any number of two or more gates, with any combination of one or more of the gates having varying sheet resistance as described herein.

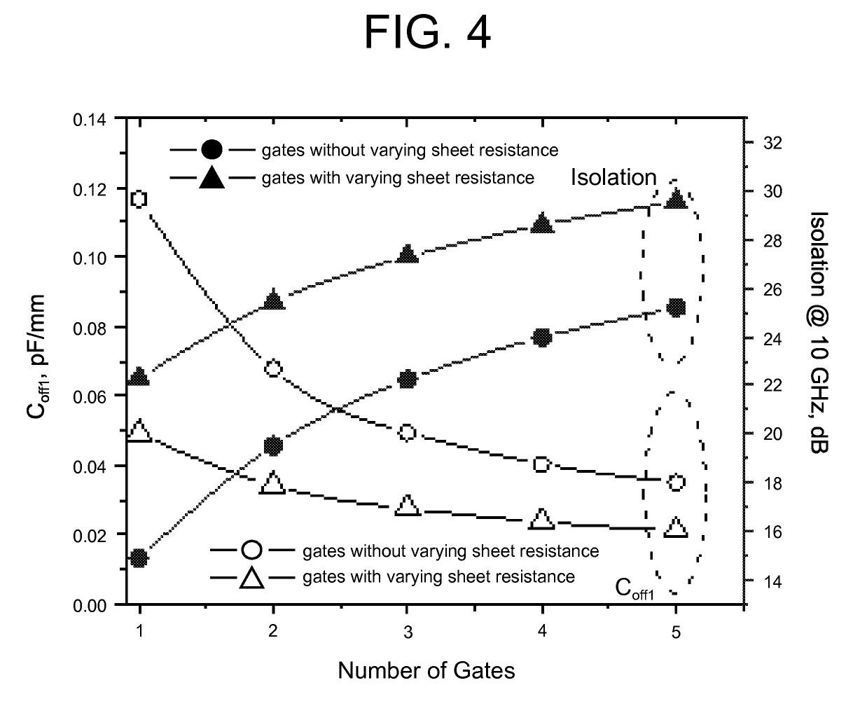

FIG. 4 shows simulated off-state capacitances and radio frequency isolations as a function of the number of gates for illustrative field effect transistors according to an embodiment. In the simulations, HFETs with sets of identical gates were used. The gate(s) for one set of HFETs, represented by the triangles, were composite gates as shown and described in FIG. 1A with layer 36 having a width 37 that is approximately twice the width of layer 38, while the gate(s) for the other set of HFETs, represented by the circles, were typical gates without varying sheet resistance (e.g., were implemented using only layer 38). As illustrated, use of the composite gate(s) provided significant improvement with respect to both the off-state capacitances and radio frequency isolations over similar HFETs implemented with typical gates.

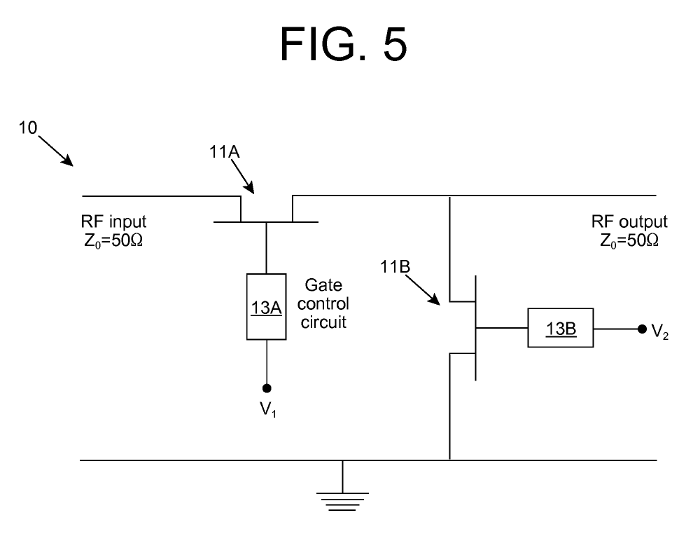

As discussed herein, the unique FETs shown and described herein can be implemented in an RF switch. To this extent, FIG. 5 shows an illustrative RF coplanar waveguide circuit 10 according to an embodiment. Circuit 10 includes a series FET 11A and a shunt FET 11B, each of which is configured to operate as an RF switch. As illustrated, series FET 11A is electrically connected between an input signal electrode and an output signal electrode of circuit 10, while shunt FET 11B is electrically connected between the signal and the ground for the circuit 10. Series FET 11A includes a gate that is controlled by an output of a gate control circuit 13A. Similarly, shunt FET 11B includes a gate that is controlled by an output of a gate control circuit 13B. While shown including a single series FET 11A and shunt FET 11B, it is understood that circuit 10 can include two or more series FETs 11A and/or two or more shunt FETs 11B. In an embodiment, one or more of FETs 11A, 11B includes a gate structure having a varying sheet resistance as shown and described herein.

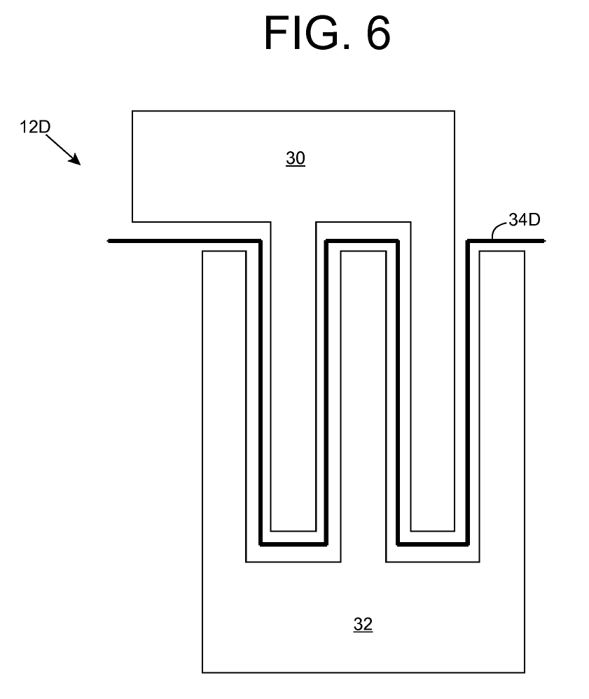

FIG. 6 shows an illustrative field effect transistor 12D layout according to an embodiment. FET 12D comprises a large periphery, multi-finger device (e.g., switch integrated circuit), which includes multiple spacings between source 30 and drain 32. FET 12D includes a gate structure 34D comprising a multi-segment line having a varying sheet resistance as shown and described herein. In this embodiment, gate structure 34D includes a single gate providing gate control for multiple spacings of FET 12D using a single contact pad. It is understood that FET 12D is only an illustrative layout, and various alternative multi-finger layouts can be implemented according to embodiments of the invention.

Aspects of the invention further provide a method of manufacturing each of the FETs and/or circuits described herein. In particular, each of the various structures described herein can be formed (e.g., deposited, grown, etched, and/or the like) on an adjacent structure, or an intervening structure, using any solution. For example, referring to FIG. 1A, FET 12A can be manufactured by obtaining first structure 20, forming second structure 22 on first structure 20, and forming insulating structure 24 on second structure. Subsequently, contacts 30, 32 can be formed on first structure, and gate structure 34A can be formed on insulating layer 24. The formation of gate structure 34A includes forming at least one gate having a sheet resistance that varies along a corresponding width 37 of the gate between source contact 30 and drain contact 32. Using gate structure 34A as an illustrative example, the forming can include forming a first layer 36 having a first width and a first sheet resistance in a location between source contact 30 and drain contact 32, and forming a second layer 38 having a second width and a second sheet resistance different from the first sheet resistance such that the second layer 38 at least partially covers the first layer 36.

When the sheet resistance of the first layer 36 of a gate is higher than the sheet resistance of the second layer 38, the second layer 38 can be formed as shown in FIG. 1A, within a central portion of first layer 36. However, as shown in FIG. 2, when the sheet resistance of the second layer 46 is higher than the sheet resistance of the first layer 44, the second layer 46 can be formed as shown in FIG. 2, in which the second layer 46 covers and extends beyond the first layer 44. Alternatively, the layer having the higher sheet resistance (e.g., layer 46) can extend beyond the layer having the lower sheet resistance (e.g., layer 44) only in a direction towards source contact 30. Further, it is understood that the gate structure of the current invention can be formed directly on second structure 22, rather than on insulating structure 24. Still further, it is understood that the forming of each structure, gate, contact, and/or the like, can include the application/removal of one or more masks and/or the like, to shape a desired geometry of the corresponding structure, gate, contact, and/or the like.

Returning to FIG. 1A, aspects of the invention provide a method of manufacturing a device including a radio frequency switch that includes electrically connecting a RF signal source to source contact 30, electrically connecting a RF signal output to drain contact 32, and electrically connecting an output of a gate control circuit to each gate in gate structure 34A. In FIG. 1A, the output can be electrically connected to second layer 38. In FIG. 2, the output can be electrically connected to first layer 44. In FIG. 3, the output can be individually electrically connected to each layer 50A-B, 52A-B. Illustrative devices include radars, detectors, power amplifiers, rectifiers, wireless communication units, all types of power converters, and/or the like. To this extent, aspects of the invention provide a operating a device including a radio frequency switch that includes selectively enabling a radio frequency signal to pass from source contact 30 to drain contact 32 by applying an output of a gate control circuit to each of a set of gates in gate structure 34A.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to an individual in the art are included within the scope of the invention as defined by the accompanying claims.

What is claimed is:

1. A field effect transistor (FET) comprising:
a device channel;
a source contact to the device channel;
a drain contact to the device channel; and
a gate structure located over the device channel and between the source contact and the drain contact, wherein the gate structure includes at least one gate having a varying sheet resistance in a direction between the source contact and the drain contact.

2. The FET of claim 1, wherein the at least one gate includes:
a first layer having a first sheet resistance; and
a second layer having a second sheet resistance lower than the first sheet resistance.

3. The FET of claim 2, wherein the first layer is wider than the second layer.

4. The FET of claim 3, wherein the first layer extends beyond the second layer towards one of: the source contact or both the source contact and the drain contact.

5. The FET of claim 2, wherein the second layer is located directly on the first layer.

6. The FET of claim 2, wherein the first layer is located directly on the second layer.

7. The FET of claim 1, further comprising an insulating structure located between the channel and the at least one gate.

8. The FET of claim 1, wherein the gate structure further includes at least one gate having a uniform sheet resistance.

9. The FET of claim 1, wherein the source contact and the drain contact form a plurality of source-drain spacings, and wherein the gate structure includes a gate within each of the plurality of source-drain spacings.

10. A circuit comprising:
a radio frequency (RF) signal input;
a RF signal output;
a field effect transistor (FET) configured to operate as a radio frequency switch, the FET including:
a device channel;
a source contact to the device channel electrically connected to the RF signal input;
a drain contact to the device channel electrically connected to at least one of: the RF signal output or a ground; and
a gate structure located over the device channel and between the source contact and the drain contact, wherein the gate structure includes at least one gate having a varying sheet resistance in a direction between the source contact and the drain contact.

11. The circuit of claim 10, wherein the at least one gate includes:
a first layer having a first sheet resistance; and
a second layer having a second sheet resistance higher than the first sheet resistance.

12. The circuit of claim 11, wherein the first layer is wider than the second layer and extends beyond the second layer towards one of: the source contact or both the source contact and the drain contact.

13. The circuit of claim 11, wherein the second layer is located directly on the first layer.

14. The circuit of claim 11, wherein the first layer is located directly on the second layer.

15. The circuit of claim 10, wherein the source contact and the drain contact form a plurality of source-drain spacings, and wherein the gate structure includes a gate within each of the plurality of source-drain spacings

16. A field effect transistor (FET) comprising:
a gate structure located over a device channel and between a source contact to the device channel and a drain contact to the device channel, wherein the gate structure includes at least one gate having a varying sheet resistance in a direction between the source contact and the drain contact.

17. The FET of claim 16, wherein the at least one gate includes:
a first layer having a first sheet resistance; and
a second layer having a second sheet resistance lower than the first sheet resistance, wherein the first layer extends beyond the second layer towards one of: the source contact or both the source contact and the drain contact.

18. The FET of claim 17, further comprising an insulating structure located between the channel and the at least one gate.

19. The FET of claim 18, wherein the insulating structure includes a dielectric material selected from the group consisting of: SiO₂, HfO₂, and a SiN compound.

20. The FET of claim 17, wherein the FET comprises a heterostructure FET comprising at least one layer of group-III nitride material.
